(19) United States
(12) Patent Application Publication
(10) Pub. No.: US 2026/0096419 A1
(43) Pub. Date: Apr. 2, 2026

(54) SEMICONDUCTOR DEVICE

(71) Applicant: Socionext Inc., Kanagawa (JP)

(72) Inventors: Atsushi OKAMOTO, Yokohama (JP); Hirotaka TAKENO, Yokohama (JP); Wenzhen WANG, Yokohama (JP)

(21) Appl. No.: 19/412,052

(22) Filed: Dec. 8, 2025

Related U.S. Application Data
(63) Continuation of application No. PCT/JP2023/021508, filed on Jun. 9, 2023.

(51) Int. Cl. H10W 20/41; H02M 7/537; H10W 20/42; H10W 20/43

(52) U.S. Cl. CPC H10W 20/427; H02M 7/537; H10W 20/42; H10W 20/43; H10W 20/435

(57) ABSTRACT

A semiconductor device includes a substrate, a first power supply line supplied with a first potential, a second power supply line supplied with a second potential, and a third power supply line supplied with a third potential, the first power supply line, the second power supply line, and the third power supply line being formed below the upper surface of the substrate, a first transistor formed above the substrate and arranged at a position overlapping the first power supply line in a plan view, a second transistor formed above the substrate, and a first via formed in the substrate and connected to a source of the first transistor and the first power supply line.

### CROSS-REFERENCE TO RELATED APPLICATIONS

This application is a continuation application of International Application No. PCT/JP2023/021508 filed on June 9, 2023, and designated the U.S., the entire contents of which are incorporated herein by reference.

### BACKGROUND

### 1. Technical Field

The present invention relates to a semiconductor device.

### 2. Description of Related Art

It is known to provide a semiconductor device with a circuit that continuously operates within a power supply domain, where a power supply switch circuit or similar component controls supplying or stopping of a power supply potential. When the circuit that continuously operates is a buffer, it is referred to as an “always-on buffer” (AOB).

Backside power delivery network (BS-PDN) technology for supplying a power supply potential from a wiring formed on the back surface of a semiconductor substrate to an element, such as a transistor formed on the front surface of the semiconductor, is known. A technology of directly connecting vias to a source and a drain of a transistor provided on the front surface of a semiconductor substrate from the back surface of the semiconductor substrate is known.

Patent Document 1: U.S. Patent Application Publication No. 2022/0344263

Patent Document 2: U.S. Patent Application Publication No. 2022/0208757

Patent Document 3: U.S. Patent Application Publication No. 2021/0272903

Patent Document 4: U.S. Patent Application Publication No. 2019/0305773

Patent Document 5: International Publication No. WO 2020/065916

Patent Document 6: International Publication No. WO 2020/066797

Patent Document 7: International Publication No. WO 2021/079511

### SUMMARY

According to an aspect of the present disclosure, a semiconductor device includes a substrate, a first power supply line supplied with a first potential, a second power supply line supplied with a second potential, and a third power supply line supplied with a third potential, the first power supply line, the second power supply line, and the third power supply line being formed below the upper surface of the substrate, a first transistor formed above the substrate and arranged at a position overlapping the first power supply line in a plan view, a second transistor formed above the substrate, and a first via formed in the substrate and connected to a source of the first transistor and the first power supply line.

### BRIEF DESCRIPTION OF THE DRAWINGS

FIG. 1 is a plan view illustrating an example of a layout in a semiconductor device according to a first embodiment;

FIG. 2 is a cross-sectional view illustrating an example of a cross-sectional structure of the semiconductor device of FIG. 1;

FIG. 3 is a circuit diagram illustrating an example of a circuit arranged in a standard cell block of FIG. 1;

FIG. 4 is a plan view illustrating an example of a positional relationship between power supply lines and vias arranged in a power supply domain PD2 of FIG. 3 and an AOB in a plan view on a back surface side of a semiconductor substrate;

FIG. 5 is a plan view illustrating an example of a layout in the AOB illustrated in FIG. 4;

FIG. 6 is a cross-sectional view illustrating an example of a cross section taken along line X1-X1’ in FIG. 5;

FIG. 7 is a cross-sectional view illustrating another example of the cross section taken along line X1-X1’ in FIG. 5;

FIG. 8 is a cross-sectional view illustrating another example of the cross section taken along line X1-X1’ in FIG. 5;

FIG. 9 is a cross-sectional view illustrating yet another example of the cross section taken along line X1-X1’ in FIG. 5;

FIG. 10 is a plan view illustrating a modified example of a layout of the AOB illustrated in FIG. 4;

FIG. 11 is a plan view illustrating an example of a layout in an AOB in a semiconductor device according to a second embodiment;

FIG. 12 is a plan view illustrating an example of a layout of the AOB illustrated in FIG. 11;

FIG. 13 is a plan view illustrating an example of the positional relationship between power lines and vias arranged at positions overlapping the standard cell block of FIG. 3 in a plan view and an AOB in a semiconductor device of the third embodiment;

FIG. 14 is a plan view illustrating an example of a layout of the AOB illustrated in FIG. 13;

FIG. 15 is a plan view illustrating an example of a layout in an AOB in a semiconductor device according to a fourth embodiment; and FIG. 16 is a circuit diagram illustrating an example of a circuit arranged in a standard cell block in a semiconductor device of a fifth embodiment.

### DETAILED DESCRIPTION

In applying a technique for directly connecting vias to the sources and drains of transistors on the surface of a semiconductor substrate to an AOB, the specific arrangement and connection of wirings, vias, and related components have not been thoroughly investigated.

According to the technology disclosed herein, it is possible to efficiently arrange buffers that include transistors whose sources and drains are directly connected to wirings located under a substrate via vias.

Hereinafter, embodiments will be described with reference to the drawings. In the descriptions hereinafter, a symbol indicating a signal is also used as a symbol indicating a signal line or a signal terminal. A symbol indicating a power supply potential is also used as a symbol indicating a power supply line or a power supply terminal to which the power supply potential is supplied.

### First Embodiment

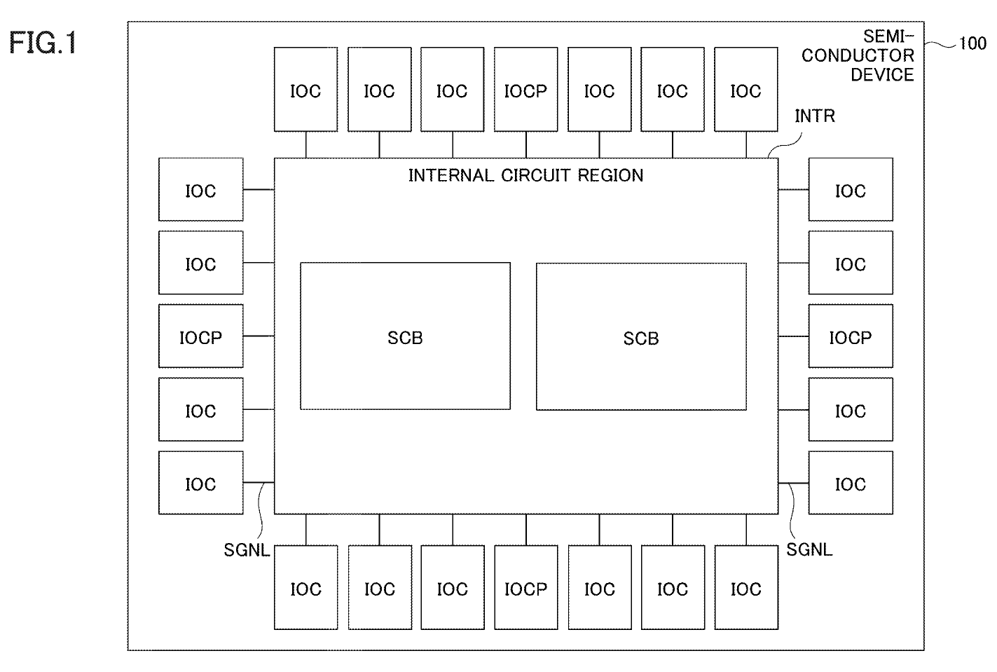

FIG. 1 illustrates an example of a layout in a semiconductor device according to the first embodiment. For example, the semiconductor device 100 illustrated in FIG. 1 may be a system-on-a-chip (SoC), a single field-programmable gate array (FPGA), or the like.

The semiconductor device 100 includes a plurality of I/O cells IOC and IOCP and an internal circuit region INTR. The I/O cell IOC is an interface circuit for a signal SGNL such as an input signal, an output signal, or an input/output signal. The I/O cell IOCP is an interface circuit for a power supply potential or a ground potential.

The I/O cells IOC and IOCP are connected to the internal circuit region INTR. For example, the internal circuit region INTR includes one or more standard cell blocks SCB in which standard cells are provided. In the internal circuit region INTR, a logic circuit other than the standard cell may be included, or a memory may be included. A memory may be included in the standard cell block SCB.

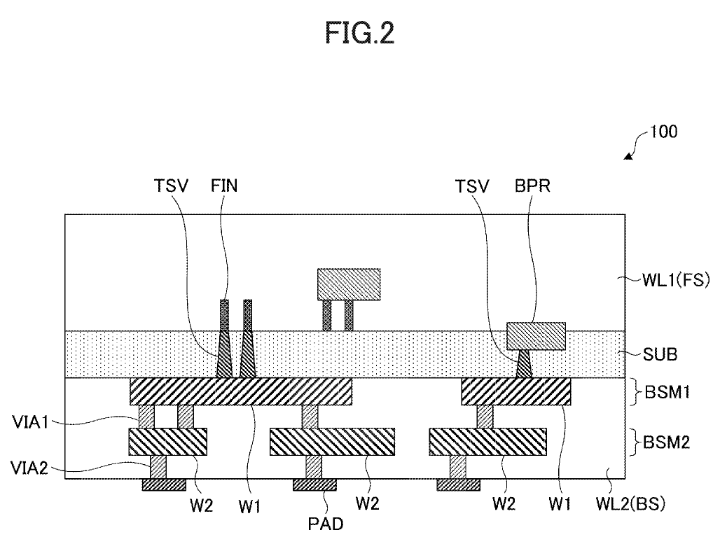

FIG. 2 illustrates an example of a cross-sectional structure of the semiconductor device 100 of FIG. 1. The semiconductor device 100 includes a substrate SUB, a wiring layer WL1 formed on a front surface side FS of the substrate SUB, and a wiring layer WL2 formed on a back surface side BS of the substrate SUB. The front surface side FS of the substrate SUB is an example of an upper surface of the substrate SUB or a side above the substrate SUB, and the back surface side BS of the substrate SUB is an example of a side below the substrate SUB. A fin FIN, which is a part of a transistor, is formed on the surface of the substrate SUB. The fin FIN has a source, a drain, and a channel. A pad PAD, which is an external connection terminal, is formed on the surface (back surface) of the wiring layer WL2 opposite to the substrate SUB.

The wiring layer WL2 includes a plurality of wiring layers BSM1 and BSM2 (two layers in FIG. 2, and BSM is an abbreviation of “backside metal”). For example, the wiring layers BSM1 and BSM2 are respectively formed with wirings W1 and W2 that respectively supply a power supply potential and a ground potential. The wirings W1 and W2 are connected to each other through a via VIA1. The wiring W2 and the pad PAD are connected to each other through a via VIA2.

The wiring W1 is coupled to the source and the drain of the fin FIN via a through silicon via (TSV) formed in the substrate SUB. The wiring W1 may be coupled to a buried wiring buried power rail (BPR) buried in the surface of the substrate SUB via the TSV. The TSV is an example of a via.

The transistor formed on the substrate SUB is not limited to a fin field effect transistor (FET) using a fin. For example, the transistor formed on the substrate SUB may be a planar metal oxide semiconductor FET (MOSFET), a nanosheet FET, or a complementary FET (CFET).

In the planar MOSFET and the nanosheet FET, the TSV that supplies a power supply potential or a ground potential is connected to a source and a drain of the transistor. In the case of the CFET, the TSV that supplies a power supply potential or a ground potential may be connected to a source and a drain located closest to the substrate SUB.

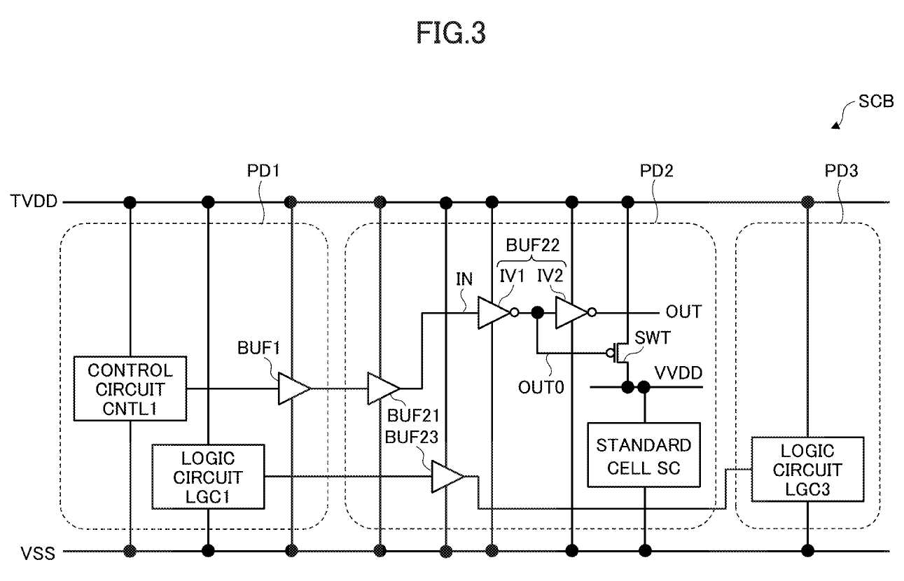

FIG. 3 illustrates an example of a circuit arranged in the standard cell block SCB of FIG. 1. In the example illustrated in FIG. 3, the standard cell block SCB has power supply domains PD1, PD2, and PD3 to which the power supply potential TVDD and the ground potential VSS are supplied. The power supply potential TVDD is an example of a second potential, and the power supply line TVDD is an example of a second power supply line. The ground potential VSS is an example of a first potential, and the ground line VSS is an example of a first power supply line.

The power supply domain PD1 has a control circuit CNTL1, a logic circuit LGC1, and a buffer BUF1 which operate in response to the power supply potential TVDD and the ground potential VSS. The power supply domain PD2 has a buffer BUF21, a buffer BUF22, and a buffer BUF23, and a switch transistor SWT, all of which operate in response to the constantly supplied power supply potential TVDD and the ground potential VSS. The power supply domain PD2 also has a standard cell SC, which operates in response to the virtual power supply potential VVDD and the ground potential VSS.

The power supply domain PD3 has a logic circuit LGC3, which operates in response to the power supply potential TVDD and the ground potential VSS. The virtual power supply potential VVDD is an example of a third potential, and the virtual power supply line VVDD is an example of a third power supply line.

The buffer BUF21 receives a control signal that is from the control circuit CNTL1 of the power supply domain PD1 via the buffer BUF1 and outputs the control signal as an input signal IN to the buffer BUF22. The buffer BUF22 has an inverter IV1 and an inverter IV2 connected in series. The inverter IV1 receives the input signal IN and outputs an output signal OUT0 to the inverter IV2 and the gate of the switch transistor SWT. The inverter IV2 receives the output signal OUT0 and outputs an output signal OUT.

The switch transistor SWT is a PMOS transistor having a source connected to the power supply line TVDD and a drain connected to the virtual power supply line VVDD, and operates upon receipt of a voltage of the output signal OUT0 that is output from the inverter IV1 as a gate potential. In other words, an on/off state of the switch transistor SWT is controlled by the control circuit CNTL1, and the supply of the virtual power supply potential VVDD is started or stopped in accordance with an on/off state of the switch transistor SWT.

The buffers BUF21 and BUF22 arranged in the power supply domain PD2 operate even when the switch transistor SWT is off, in which the virtual power supply potential VVDD is not supplied. Therefore, in the power supply domain PD2 having the standard cell SC that operates at the virtual power supply potential VVDD, an on/off state of the switch transistor SWT can be controlled by a control signal that is output from the control circuit CNTL1 of the power supply domain PD1.

While the switch transistor SWT is on, the power supply line TVDD and the virtual power supply line VVDD are electrically connected to each other, and the power supply potential TVDD is supplied to the standard cell SC via the virtual power supply line VVDD. While the switch transistor SWT is off, an electrical connection between the power supply line TVDD and the virtual power supply line VVDD is shut off, and the virtual power supply line VVDD is set to a floating state. The standard cell SC includes various logic circuits, such as a NAND circuit and an inverter. The standard cell SC may include static random access memory (SRAM) or various macros.

The buffer BUF23 receives a signal that is output from the logic circuit LGC1 of the power supply domain PD1 and outputs the received signal to the logic circuit LGC3 of the power supply domain PD3. The buffer BUF23 arranged in the power supply domain PD2 operates even when the switch transistor SWT is off, in which the virtual power supply potential VVDD is not supplied. Therefore, in the power supply domain PD2 having the standard cell SC that operates at the virtual power supply potential VVDD, it is possible to transmit the signal that is output from the logic circuit LGC1 of the power supply domain PD1 to the power supply domain PD3 via the buffer BUF23 of the power supply domain PD2.

The buffers BUF21, BUF22, and BUF23 arranged in the power supply domain PD2 capable of supplying and stopping the virtual power supply potential VVDD are capable of continuously operating and therefore sometimes referred to as an “always-on buffer” (AOB). For example, the AOB may be designed as a cell. The AOB is used to transmit a control signal for controlling a circuit, such as the switch transistor SWT in the power supply domain PD2, or to transmit a signal (a signal not used in the power supply domain PD2) between other power supply domains such as the power supply domains PD1 and PD3. The AOB is an example of a first circuit.

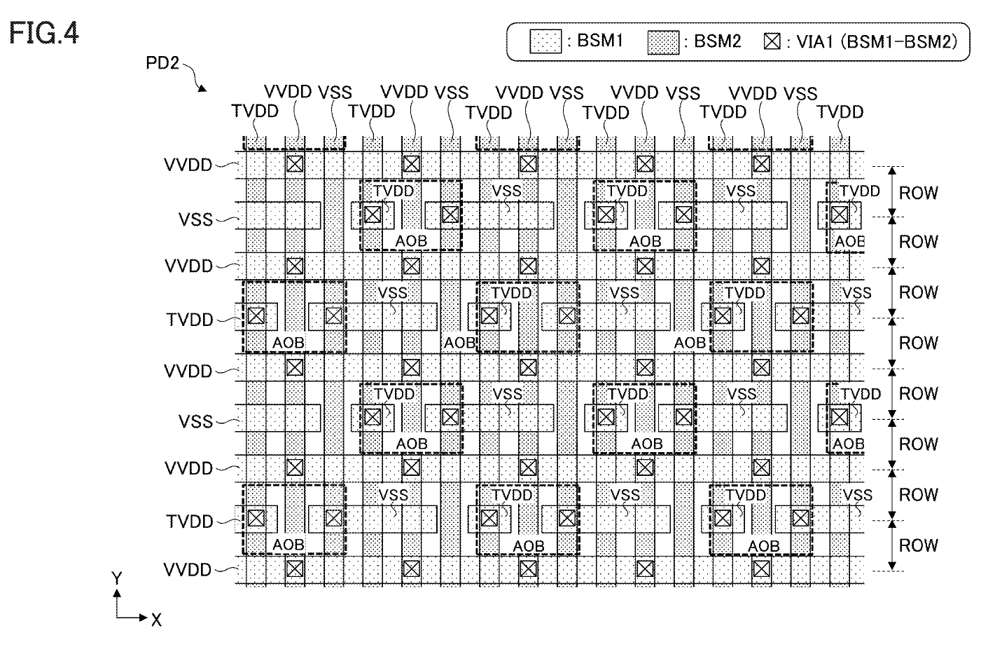

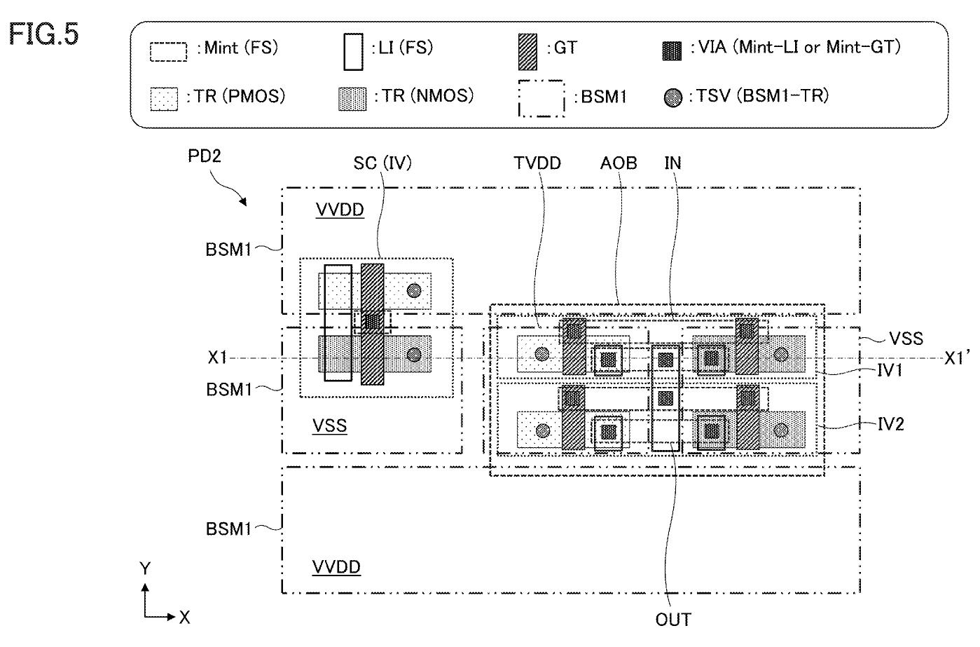

FIG. 4 illustrates an example of a positional relationship between power supply lines and vias arranged in the power supply domain PD2 of FIG. 3 and the AOB in a plan view on the back surface side of the semiconductor substrate SUB. For example, each wiring of the wiring layer BSM1 extends in an X direction, and each wiring of the wiring layer BSM2 extends in a Y direction, which differs from the X direction. The X direction is an example of a first direction, and the Y direction is an example of a second direction. The symbol “ROW” shown in FIG. 4 indicates a width of the standard cell SC in the Y direction in the wiring layer BSM1.

The virtual power supply lines VVDD of the wiring layer BSM1 are arranged in the Y direction at a pitch twice as large as ROW. Between pairs of the virtual power supply lines VVDD adjacent to each other in the Y direction, alternately arranged along the X direction are the ground lines VSS extending in the X direction and interrupted at a plurality of locations partway along the ground lines VSS and the power supply lines TVDD arranged at locations where the ground lines VSS are interrupted. In other words, the power supply lines TVDD are arranged between a plurality of ground lines VSS in the X direction.

The AOBs indicated by a thick broken-line frame are arranged alternately (staggered), for example, at positions overlapping a part of the power supply line TVDD and a part of the ground line VSS in a plan view. In a region where the AOBs are not arranged, for example, standard cells SC (not illustrated) are arranged.

Arranging the power supply lines TVDD in a dispersed manner at positions where the ground line VSS is interrupted makes it unnecessary to arrange the power supply lines TVDD extending in the X direction in the wiring layer BSM1 together with the virtual power supply lines VVDD and the ground line VSS. The power supply lines TVDD can be arranged only at positions where the AOBs are arranged. This makes it possible to increase the arrangement density of the virtual power supply lines VVDD and the ground lines VSS in the wiring layer BSM1 and enhance the power supply capability to the standard cells SC, as compared with the case where a dedicated region for the power supply lines TVDD arranged at the interval ROW is provided.

In the wiring layer BSM2, the power supply line TVDD, the virtual power supply line VVDD, and the ground line VSS are arranged in a repeating pattern in the X direction. The virtual power supply lines VVDD of the wiring layers BSM1 and BSM2 are connected to each other through the vias VIA1 arranged at the intersections. The power supply lines TVDD of the wiring layers BSM1 and BSM2 are connected to each other through the vias VIA1 arranged at the intersections. The ground lines VSS of the wiring layers BSM1 and BSM2 are connected to each other through the vias VIA1 arranged at the intersections.

The virtual power supply lines VVDD may be omitted in the wiring layer BSM2. In this case, in the wiring layer BSM2, the power supply lines TVDD and the ground lines VSS may be alternately arranged along the X direction.

The arrangement density of the AOB is set in accordance with the number of AOBs required to be arranged in the power supply domain PD2. In this case, the interval of interruption in the ground lines VSS extending in the X direction in the wiring layer BSM1 may be changed, and the arrangement interval of the power supply lines TVDD in the Y direction in the wiring layer BSM1 may be changed.

FIG. 5 is a plan view illustrating an example of a layout in the AOB illustrated in FIG. 4. The AOB illustrated in FIG. 5 represents the buffer BUF22 illustrated in FIG. 3, but may be the buffer BUF21 or the buffer BUF23 illustrated in FIG. 3. In the legends shown in FIG. 5 and the subsequent plan views, the symbol “LI” denotes a local wiring formed on the substrate SUB. The wiring LI can be directly connected to a source and a drain of the transistor. The symbol “Mint” denotes a wiring formed in the metal wiring layer Mint, which is a wiring layer on the wiring LI. The symbol “GT” denotes a gate of the transistor. The symbol “VIA” denotes a via that connects the Mint wiring and the local wiring LI or a via that connects the Mint wiring and the gate GT.

The symbol “TR (PMOS)” denotes a transistor region (source, drain, and channel) of a PMOS transistor. The symbol “TR (NMOS)” denotes a transistor region (source, drain, and channel) of a NMOS transistor. The PMOS transistor is an example of a second transistor, and the NMOS transistor is an example of a first transistor.

For example, in the fin FET, a fin is formed in the region TR. In the nanosheet FET, a semiconductor layer is formed as a source and a drain in the region TR, and a nanosheet as a channel is formed between the source and the drain.

As illustrated in FIG. 4, the AOBs are arranged at positions overlapping a part of the power supply line TVDD and a part of the ground line VSS in the wiring layer BSM1 in a plan view. The NMOS transistors of the inverters IV1 and IV2 included in the AOB are arranged at a position overlapping the ground line VSS of the wiring layer BSM1 in a plan view. The PMOS transistors of the inverters IV1 and IV2 included in the AOB are arranged at a position overlapping the power supply line TVDD of the wiring layer BSM1 in a plan view.

The sources of the NMOS transistors of the inverters IV1 and IV2 are directly connected to the ground line VSS of the wiring layer BSM1 via the TSVs. The sources of the PMOS transistors of the inverters IV1 and IV2 are directly connected to the power supply line TVDD of the wiring layer BSM1 via the TSVs. As a result, the power supply potential TVDD and the ground potential VSS can be directly supplied to the sources of the transistors of the AOB from the back surface side of the substrate SUB (FIG. 2), and the layout size of the AOB can be reduced to efficiently arrange the AOB.

The direct connection means that a conductor included in the TSV is in contact with a source, a drain, or the like of each transistor, and also includes, for example, a case where the TSV includes a plurality of layers of conductors, a part of the plurality of layers of conductors being in contact with the source or the drain of the transistor.

The power supply line TVDD and the ground line VSS in the wiring layer BSM1 are connected to the corresponding power supply line TVDD and ground line VSS in the wiring layer BSM2 (not illustrated), respectively. In the case where the virtual power supply line VVDD is arranged in the wiring layer BSM2, the virtual power supply line VVDD of the wiring layer BSM1 may be connected to the virtual power supply line VVDD of the wiring layer BSM2.

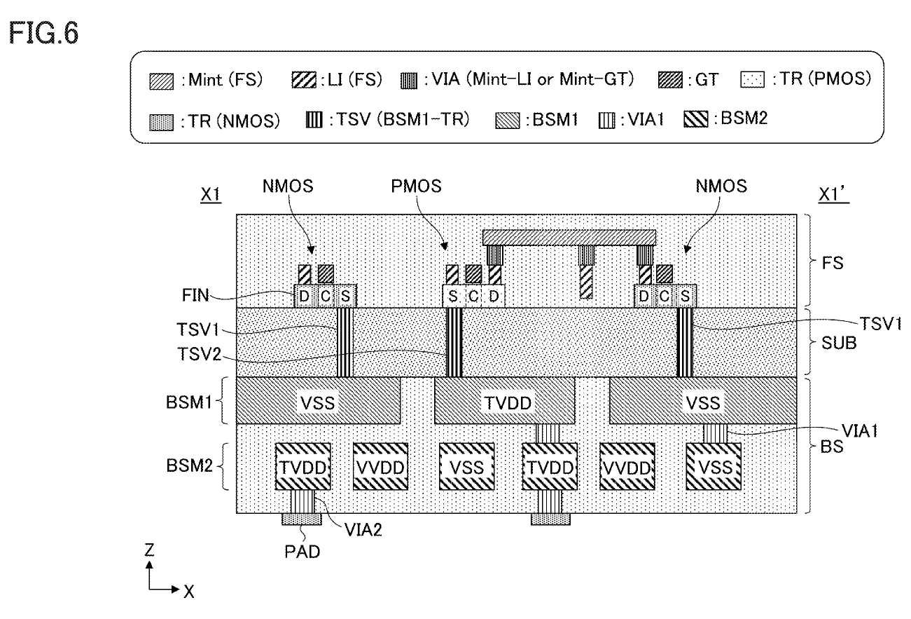

FIG. 6 illustrates an example of a cross section taken along line X1-X1’ in FIG. 5. The ground line VSS formed in the wiring layer BSM1 on the back surface side BS of the substrate SUB is connected to the source S (N-type impurity region) of the NMOS transistor formed on the front surface FS of the substrate SUB via the TSV1 formed in the substrate SUB. Similarly, the power supply line TVDD formed in the wiring layer BSM1 on the back surface side BS is connected to the source S (P-type impurity region) of the PMOS transistor formed on the front surface FS via the TSV2 formed in the substrate SUB.

In each fin FIN, a channel C is arranged between a source S and a drain D. A gate GT is arranged on the channel C via a gate insulating film (not illustrated). In FIG. 6, two wiring layers BSM1 and BSM2 are arranged on the back surface side BS, but three or more wiring layers BSM may be arranged.

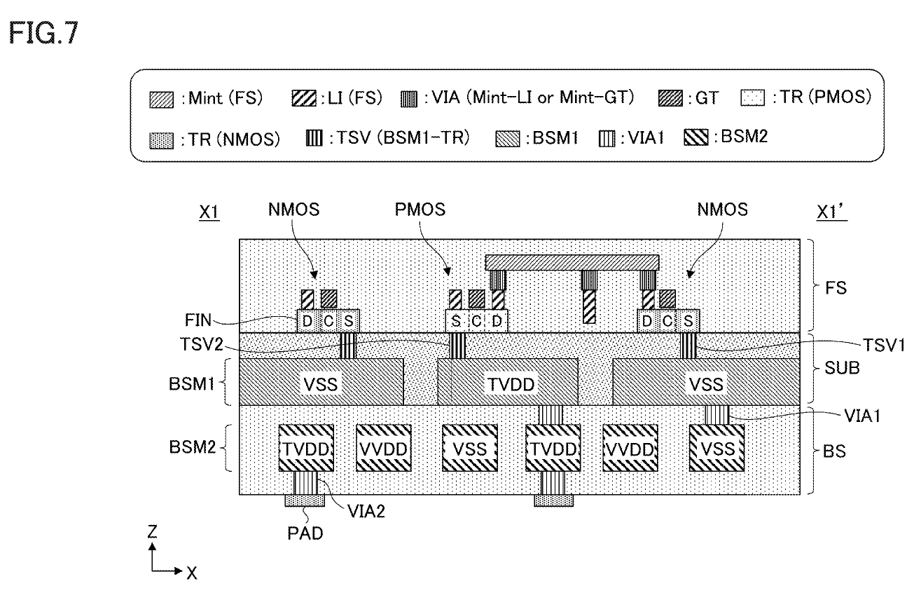

FIG. 7 illustrates another example of the cross section taken along line X1-X1’ in FIG. 5. Elements and layouts identical or similar to those of FIG. 6 are denoted by the same symbols or the same pattern, and detailed description thereof is omitted. FIG. 7 is similar to the cross-sectional structure of FIG. 6, except that the positions at which the wirings of the wiring layer BSM1 are formed are different. The wirings of the wiring layer BSM1 are formed below the substrate SUB on the back surface BS side of the substrate SUB.

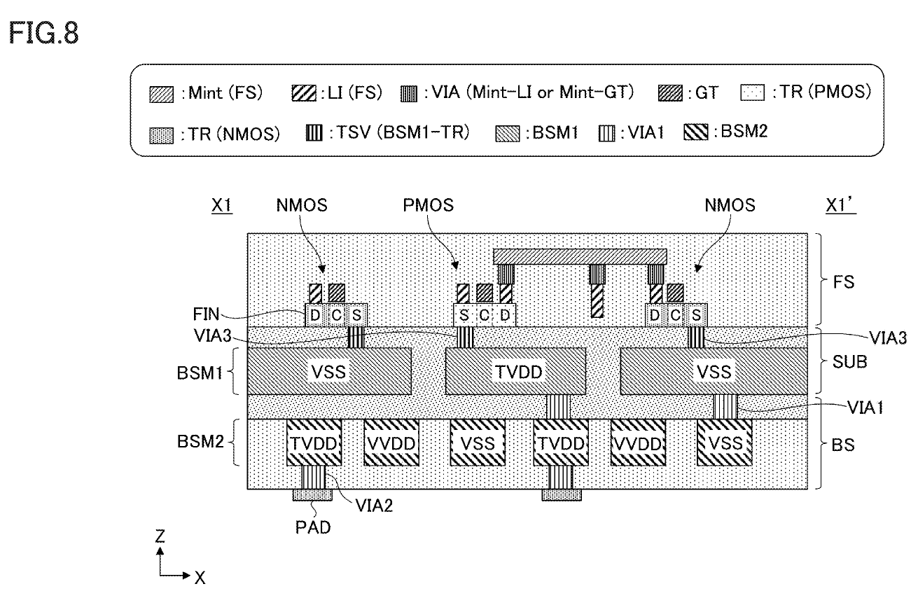

FIG. 8 illustrates another example of the cross section taken along line X1-X1’ in FIG. 5. Elements and layouts identical or similar to those of FIG. 6 are denoted by the same symbols or the same pattern, and detailed description thereof is omitted. FIG. 8 is similar to the cross-sectional structure of FIG. 6, except that the positions at which the wirings of the wiring layer BSM1 are formed are different. The wiring of the wiring layer BSM1 is not exposed to the back surface side BS of the substrate SUB, but is formed inside the substrate SUB. The wiring of the wiring layer BSM1 formed in the substrate SUB is connected to the wiring of the wiring layer BSM2 via the via VIA1 formed in the substrate SUB, and is connected to the source S of the fin FIN via a via VIA3 formed in the substrate SUB.

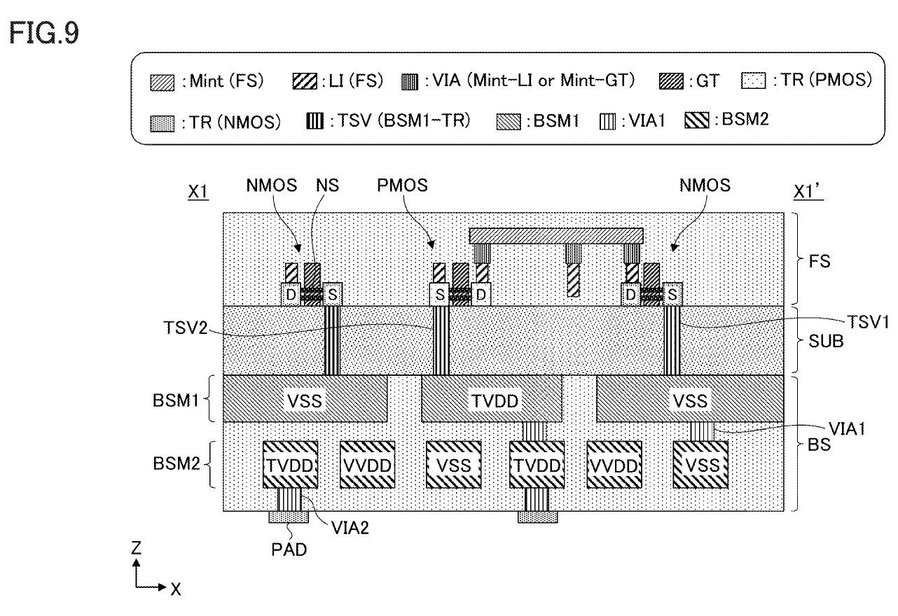

FIG. 9 illustrates yet another example of the cross section taken along line X1-X1’ in FIG. 5. Elements and layouts identical or similar to those of FIG. 6 are denoted by the same symbols or the same pattern, and detailed description thereof is omitted. FIG. 9 is the same as the cross-sectional structure of FIG. 6 except that the transistor formed on the substrate SUB is a nanosheet FET. The nanosheet FET includes a semiconductor layer having a source S and a drain D, a nanosheet NS having a semiconductor material formed between the source S and the drain D, and a gate electrode GT formed with a gate insulating film (not illustrated) interposed between the gate electrode GT and the nanosheet NS. The nanosheet FET may be arranged instead of the fin FET illustrated in FIGS. 6, 7 or 8.

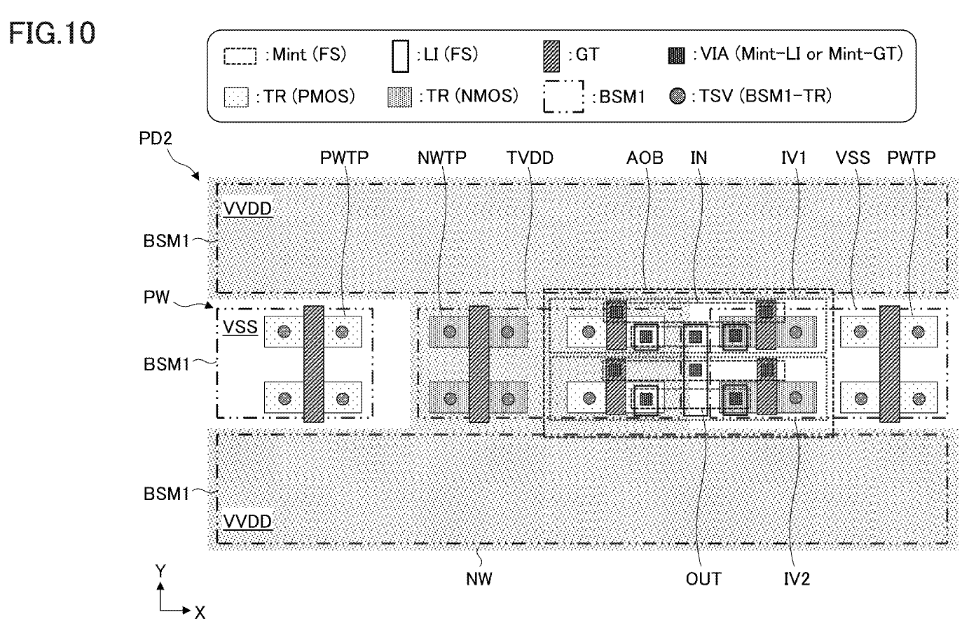

FIG. 10 is a plan view illustrating a modified example of a layout in the AOB illustrated in FIG. 4. Elements and layouts identical or similar to those of FIG. 5 are denoted by the same symbols or the same pattern, and detailed description thereof is omitted. The layout of FIG. 10 is the same as that of FIG. 5 except that an N-type well tap NWTP and a P-type well tap PWTP are arranged in regions adjacent to both sides of the AOB in the X direction. The well tap PWTP is an example of a first well tap, and the well tap NWTP is an example of a second well tap.

The well tap PWTP is arranged at a position overlapping the ground line VSS of the wiring layer BSM1 in a plan view. The well tap PWTP is formed by a PMOS transistor whose source and drain are directly connected to the ground line VSS of the wiring layer BSM1 via the TSV. This makes it possible to supply the ground potential VSS to a P-type well region PW, which is the substrate region (shaded region) of the NMOS transistor.

The well tap NWTP is arranged at a position overlapping the power supply line TVDD of the wiring layer BSM1 in a plan view. The well tap NWTP is formed by an NMOS transistor whose source and drain are directly connected to the power supply line TVDD of the wiring layer BSM1 via the TSV. This makes it possible to supply the power supply potential TVDD to an N-type well region NW, which is the substrate region (shaded region) of the PMOS transistor. As illustrated in FIG. 10, by arranging the well taps NWTP and PWTP adjacent to the region where the AOB is arranged, the design efficiency of the circuit region can be improved.

As described above, in the first embodiment, the sources of the NMOS transistor and the PMOS transistor of the AOB are directly connected to the ground line VSS and the power supply line TVDD of the wiring layer BSM1 via the TSV. As a result, the power supply potential TVDD and the ground potential VSS can be directly supplied to the AOB from the back surface side of the substrate SUB, and the layout size of the AOB can be reduced to efficiently arrange the AOB.

Arranging the power supply lines TVDD in a dispersed manner at positions where the ground line VSS is interrupted makes it unnecessary to arrange the power supply lines TVDD extending in the X direction in the wiring layer BSM1 together with the virtual power supply lines VVDD and the ground line VSS. The power supply lines TVDD can be arranged only at positions where the AOBs are arranged. Thus, as compared with the case where the power supply lines TVDD extending in the X direction are arranged in the wiring layer BSM1 together with the virtual power supply lines VVDD and the ground line VSS, it is possible to increase the arrangement density of the virtual power supply lines VVDD and the ground lines VSS in the wiring layer BSM1, and to enhance the power supply capability to the standard cell SC.

By arranging the well tap PWTP at a position overlapping the ground line VSS of the wiring layer BSM1 in a plan view, it is possible to supply the ground potential VSS to the P-type well region PW where the substrate region of the NMOS transistor is located. By arranging the well tap NWTP at a position overlapping the power supply line TVDD of the wiring layer BSM1 in a plan view, it is possible to supply the power supply potential TVDD to the N-type well region NW where the substrate region of the PMOS transistor is located.

### Second Embodiment

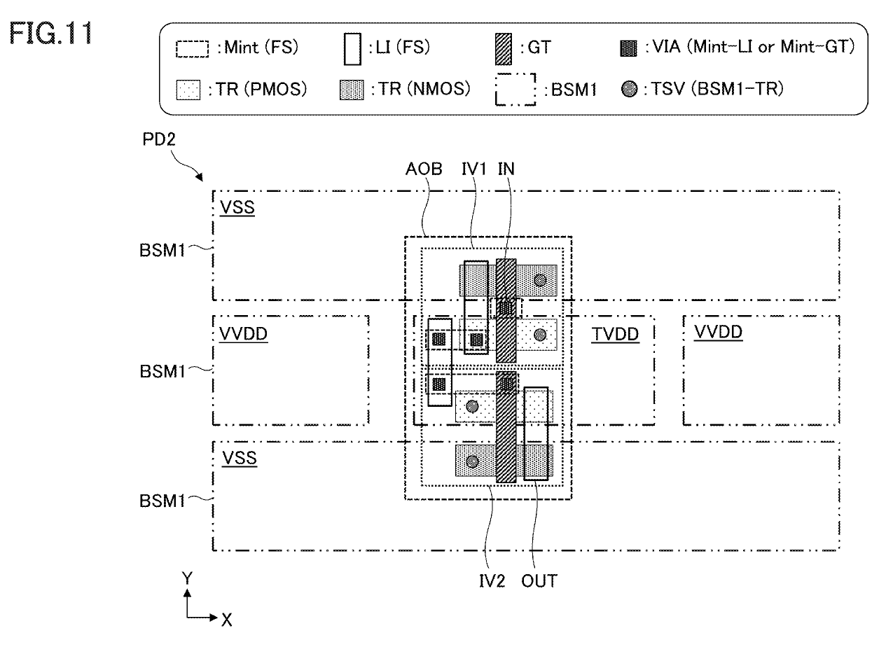

FIG. 11 is a plan view illustrating an example of a layout in the AOB in a semiconductor device according to the second embodiment. Elements and layouts identical or similar to those of FIG. 5 are denoted by the same symbols or the same pattern, and detailed description thereof is omitted. For example, the power supply domain PD2 illustrated in FIG. 11 is provided in the standard cell block SCB of FIG. 1 together with the power supply domains PD1 and PD3, as illustrated in FIG. 3.

In FIG. 11, the ground lines VSS of the wiring layer BSM1 are formed to extend in the X direction. Between pairs of the ground lines VSS adjacent to each other in the Y direction, alternately arranged along the X direction are the virtual power supply lines VVDD extending in the X direction and interrupted at a plurality of locations partway along the virtual power supply lines VVDD and the power supply lines TVDD arranged at locations where the virtual power supply lines VVDD are interrupted. As in FIG. 4, the AOBs are arranged alternately (staggered) in the power supply domain PD2.

In the case where the power supply line TVDD and the ground line VSS are arranged side by side in the Y direction in the wiring layer BSM1, the inverters IV1 and IV2 of the AOB are arranged side by side in the Y direction. The NMOS transistors of the inverters IV1 and IV2 are arranged at a position overlapping the ground line VSS of the wiring layer BSM1 in a plan view. The PMOS transistors of the inverters IV1 and IV2 are arranged at positions overlapping the power supply line TVDD of the wiring layer BSM1 in a plan view. Thus, as in FIG. 5, the source of the NMOS transistor can be directly connected to the ground line VSS of the wiring layer BSM1 via the TSV, and the source of the PMOS transistor can be directly connected to the power supply line TVDD of the wiring layer BSM1 via the TSV.

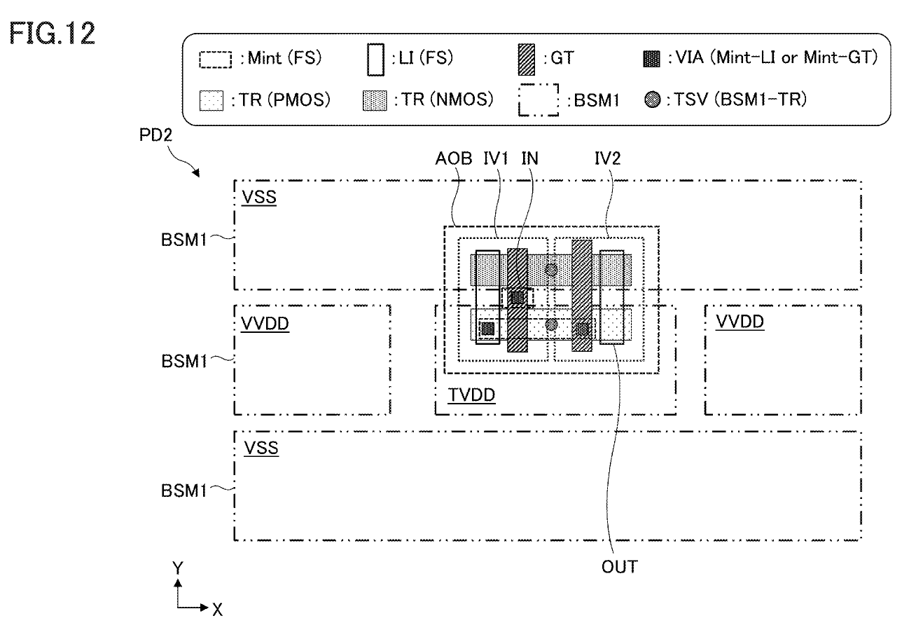

FIG. 12 is a plan view illustrating a modified example of a layout in the AOB illustrated in FIG. 11. Elements and layouts identical or similar to those of FIG. 11 are denoted by the same symbols or the same pattern, and detailed description thereof is omitted. In FIG. 12, the AOB is arranged extending across the boundary portion between the power supply line TVDD and the ground line VSS of the wiring layer BSM1, and the inverters IV1 and IV2 are arranged side by side in the X direction. The NMOS transistors of the inverters IV1 and IV2 are arranged at a position overlapping the ground line VSS of the wiring layer BSM1 in a plan view. The PMOS transistors of the inverters IV1 and IV2 are arranged at positions overlapping the power supply line TVDD of the wiring layer BSM1 in a plan view.

The sources of the PMOS transistors of the inverters IV1 and IV2 are shared and connected to the power supply line TVDD of the wiring layer BSM1 via the shared TSV. The sources of the NMOS transistors of the inverters IV1 and IV2 are shared and connected to the ground line VSS of the wiring layer BSM1 via the shared TSV.

Thus, as in FIG. 5, the source of the PMOS transistor can be directly connected to the power supply line TVDD of the wiring layer BSM1 via the TSV, and the source of the NMOS transistor can be directly connected to the ground line VSS of the wiring layer BSM1 via the TSV. By sharing the TSV, the layout size of the AOB can be made smaller than that illustrated in FIGS. 5 and 11.

The sources of the PMOS transistors of the inverters IV1 and IV2 may be provided independently of each other, and the sources of the NMOS transistors of the inverters IV1 and IV2 may be provided independently of each other. In other embodiments and modified examples, the sources of the PMOS transistors of the inverters IV1 and IV2 may be shared, and the sources of the NMOS transistors of the inverters IV1 and IV2 may be shared.

As described above, the second embodiment can also obtain effects similar to those of the first embodiment. For example, the power supply potential TVDD and the ground potential VSS can be directly supplied to the AOB from the back surface side of the substrate SUB, and the layout size of the AOB can be reduced to efficiently arrange the AOB. Similarly, in the case where the power supply line TVDD is arranged at a position where the virtual power supply line VVDD extending in the X direction is interrupted, the power supply potential TVDD and the ground potential VSS can be directly supplied to the AOB from the back surface side of the substrate SUB.

Furthermore, the sources of the PMOS transistors of the inverters IV1 and IV2 are shared and connected to the power supply line TVDD of the wiring layer BSM1 via the shared TSV. The sources of the NMOS transistors of the inverters IV1 and IV2 are shared and connected to the ground line VSS of the wiring layer BSM1 via the shared TSV. Thus, the layout size of the AOB can be further reduced and the AOB can be arranged more efficiently.

### Third Embodiment

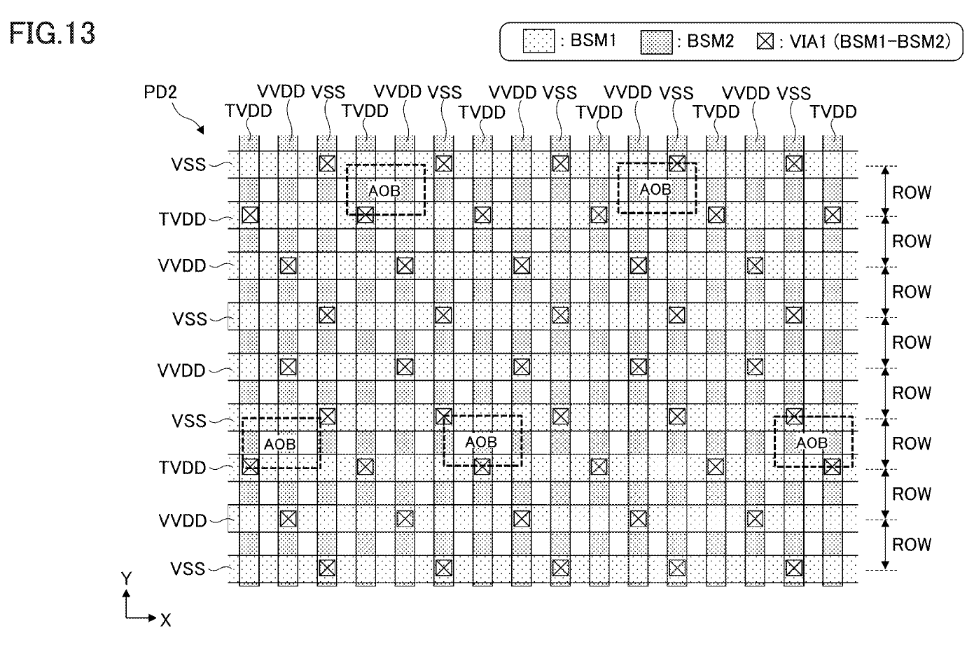

FIG. 13 illustrates an example of the positional relationship between power lines and vias arranged at positions overlapping the standard cell block of FIG. 3 in a plan view and an AOB in a semiconductor device of the third embodiment. Elements and layouts identical or similar to those of FIG. 4 are denoted by the same symbols or the same pattern, and detailed description thereof is omitted.

For example, the power supply domain PD2 illustrated in FIG. 13 is provided in the standard cell block SCB of FIG. 1 together with the power supply domains PD1 and PD3, as illustrated in FIG. 3. In this embodiment, the power supply wiring of the wiring layer BSM1 is not interrupted, and the ground line VSS, the power supply line TVDD, and the virtual power supply line VVDD extending in the X direction are arranged side by side in the Y direction. The AOB is arranged at a position overlapping the ground line VSS and the power supply line TVDD adjacent to each other in the wiring layer BSM1.

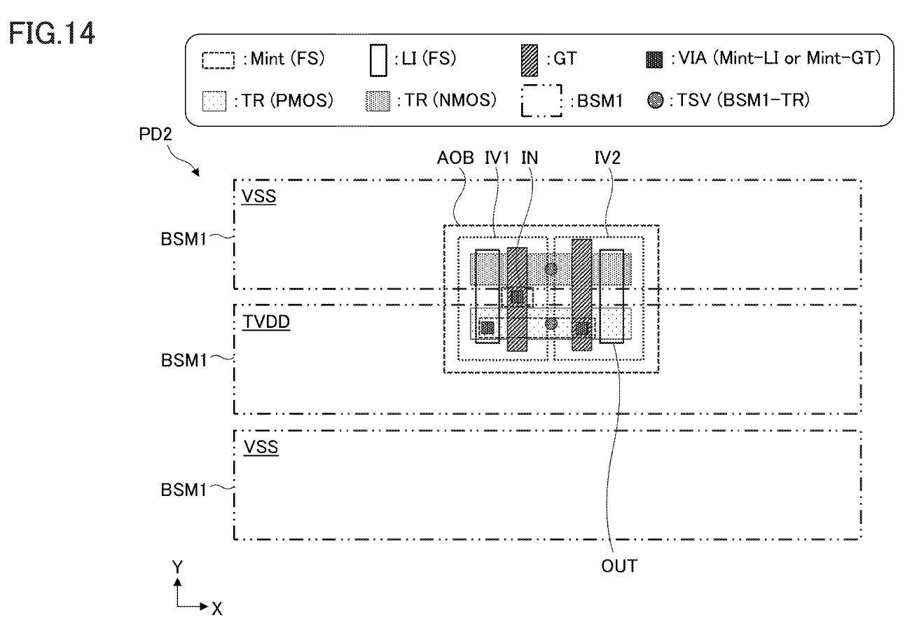

FIG. 14 is a plan view illustrating an example of a layout in the AOB illustrated in FIG. 13. Elements and layouts identical or similar to those of FIG. 5 are denoted by the same symbols or the same pattern, and detailed description thereof is omitted. The layout of the AOB illustrated in FIG. 4 is the same as or similar to the layout of the AOB illustrated in FIG. 12. In other words, the AOB is arranged extending across the boundary portion between the power supply line TVDD and the ground line VSS of the wiring layer BSM1, and the inverters IV1 and IV2 are arranged side by side in the X direction.

The sources of the PMOS transistors of the inverters IV1 and IV2 are shared and connected to the power supply line TVDD of the wiring layer BSM1 via the shared TSV. The sources of the NMOS transistors of the inverters IV1 and IV2 are shared and connected to the ground line VSS of the wiring layer BSM1 via the shared TSV.

The sources of the PMOS transistors of the inverters IV1 and IV2 may be provided independently of each other. The sources of the NMOS transistors of the inverters IV1 and IV2 may be provided independently of each other.

As described above, the third embodiment can also obtain effects similar to those of the first embodiment. For example, the power supply potential TVDD and the ground potential VSS can be directly supplied to the AOB from the back surface side of the substrate SUB, and the layout size of the AOB can be reduced to efficiently arrange the AOBs. Similarly, in the case where the power supply line TVDD of the wiring layer BSM1 is arranged to extend in the X direction, the layout size of the AOB can be reduced and the AOBs can be efficiently arranged.

### Fourth Embodiment

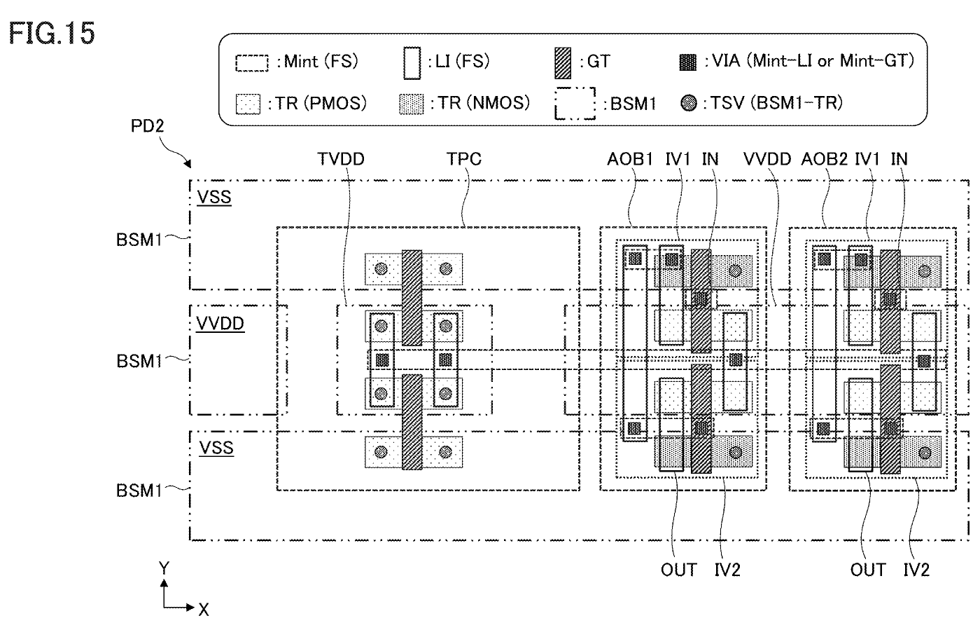

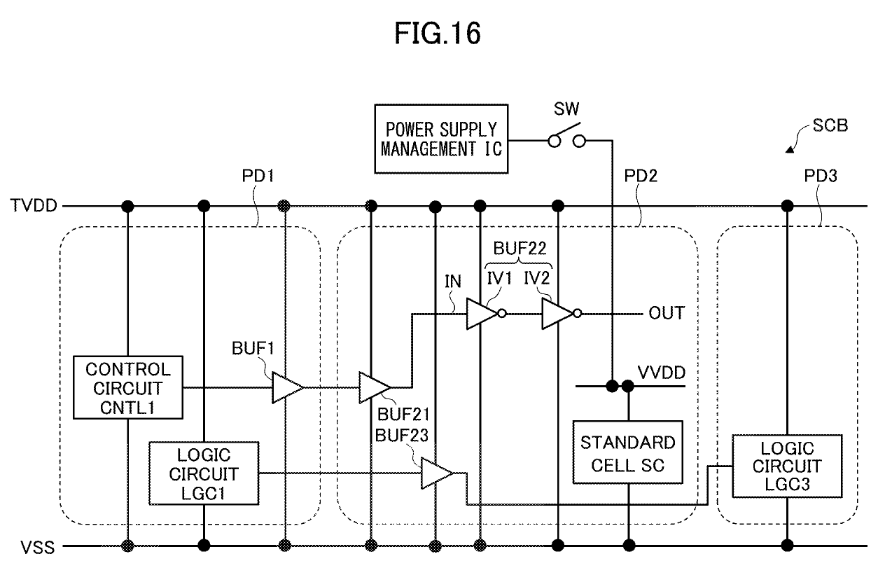

FIG. 15 illustrates an example of a layout in an AOB in a semiconductor device according to the fourth embodiment. Elements and layouts identical or similar to those of FIG. 5 are denoted by the same symbols or the same pattern, and detailed description thereof is omitted. For example, the power supply domain PD2 illustrated in FIG. 15 is provided in the standard cell block SCB of FIG. 1 together with the power supply domains PD1 and PD3, as illustrated in FIG. 3.

The layout of the ground line VSS, the virtual power supply line VVDD, and the power supply line TVDD of the wiring layer BSM1 in FIG. 15 is the same as that in FIG. 11. In other words, the ground line VSS is formed to extend in the X direction. Between pairs of the ground lines VSS adjacent to each other in the Y direction, alternately arranged along the X direction are the virtual power supply lines VVDD extending in the X direction and interrupted at a plurality of locations partway along the virtual power supply lines VVDD and the power supply lines TVDD arranged at locations where the virtual power supply lines VVDD are interrupted.

In this embodiment, a power supply tap cell TPC is arranged at a position overlapping the virtual power supply line VVDD of the wiring layer BSM1 in a plan view. Two AOBs, an AOB 1 and an AOB 2, are arranged side by side in the X direction at a position overlapping the power supply line TVDD and the ground wire VSS of the wiring layer BSM1 in a plan view.

The power supply tap cell TPC has a PMOS transistor whose source and drain are directly connected to the power supply line TVDD of the wiring layer BSM1 via a TSV. The power supply tap cell TPC has a PMOS transistor whose source and drain are directly connected to the ground wire VSS of the wiring layer BSM1 via a TSV. The source and drain of the transistor are examples of semiconductor layers.

The inverters IV1 and IV2 of each of the AOB 1 and the AOB 2 are arranged side by side in the Y direction as in FIG. 11. The PMOS transistors of the inverters IV1 and IV2 are arranged at a position overlapping the power supply line TVDD of the wiring layer BSM1 in a plan view. The sources of the PMOS transistors of the AOB 1 and the AOB 2 are connected to the sources and drains of the PMOS transistors of the power supply tap cells TPC via Mint wirings extending in the Y direction, vias VIA and local lines LI extending in the X direction. In other words, the AOB 1 and the AOB 2 receive the power supply potential TVDD supplied from the power supply tap cells TPC.

The NMOS transistors of the inverters IV1 and IV2 are arranged at positions overlapping the ground line VSS of the wiring layer BSM1 in a plan view, and the sources of the NMOS transistors are directly connected to the ground line VSS of the wiring layer BSM1 via TSV.

As illustrated in FIG. 15, in the case where the virtual power supply lines VVDD of the wiring layer BSM1 are arranged in a discontinuous manner, it is necessary to provide a predetermined space (free area) between the virtual power supply lines VVDD and the power supply lines TVDD arranged between the virtual power supply lines VVDD. In this embodiment, the power supply tap cells TPC are arranged at positions corresponding to the power supply lines TVDD of the wiring layer BSM1, and the power supply potentials TVDD are supplied from the power supply tap cells TPC to the plurality of AOBs 1 and AOBs 2.

Thus, the AOBs can be arranged not only at positions facing the power supply lines TVDD of the wiring layer BSM1 but also at positions facing the virtual power supply lines VVDD of the wiring layer BSM1. As a result, the number of power supply lines TVDD of the wiring layer BSM1 can be reduced, and the area occupied by the free area in the circuit area can be reduced. This makes it possible to suppress an increase in the element area. On the other hand, if the power supply lines TVDD of the wiring layer BSM1 are arranged at positions corresponding to the respective AOB 1 and AOB 2, the free area for the power supply lines TVDD corresponding to the respective AOB 1 and AOB 2 is required, and the element area may increase.

As described above, the fourth embodiment can also obtain effects similar to those of the first embodiment. For example, the power supply potential TVDD and the ground potential VSS can be directly supplied to the AOB from the back surface side of the substrate SUB, and the layout size of the AOB can be reduced to efficiently arrange the AOBs.

Furthermore, in the fourth embodiment, the power supply tap cell TPC arranged at a position overlapping the power supply lines TVDD of the wiring layer BSM1 in a plan view is connected to the sources of the PMOS transistors of the plurality of AOBs through a wiring. Thus, compared with the case where the power supply lines TVDD of the wiring layer BSM1 are arranged for each AOB, the number of the power supply lines TVDD of the wiring layer BSM1 can be reduced, and the area occupied by the free area in the circuit area can be reduced. As a result, an increase in the element area can be suppressed, and the total layout size of the AOB can be reduced so that the AOBs can be efficiently arranged. In FIG. 15, the power supply line TVDD of the wiring layer BSM1 is arranged at a position where the virtual power supply line VVDD is interrupted, but in the case where the power supply line TVDD is arranged at a position where the ground line VSS of the wiring layer BSM1 is interrupted, the power supply potential TVDD may be supplied from the power supply tap cell TPC to the plurality of AOBs 1 and AOBs 2. A similar configuration may be adopted in other embodiments.

### Fifth Embodiment

FIG. 16 illustrates an example of a circuit arranged in the standard cell block SCB in a semiconductor device of the fifth embodiment. The same symbols are given to the identical or similar elements as those in FIG. 3, and the detailed description thereof will be omitted. The standard cell block SCB illustrated in FIG. 16 is included in the internal circuit region INTR of the semiconductor device 100 as in FIG. 1.

The standard cell block SCB illustrated in FIG. 16 has, as in FIG. 3, power supply domains PD1 and PD3 to which the power supply potential TVDD and the ground potential are supplied, and a power supply domain PD2 to which the power supply potential VVDD and the ground potential VSS are supplied. The power supply domains PD1 and PD3 are the same as the power supply domains PD1 and PD3 in FIG. 3.

The power supply domain PD2 does not have the switch transistor SWT included in the power supply domain PD2 of FIG. 3. Then, for example, the virtual power supply potential VVDD supplied from a power supply management integrated circuit (IC) provided outside the semiconductor device 100 is supplied to the virtual power supply line VVDD in the power supply domain PD2 via the switch SW. The power supply management IC may be arranged on a board on which the semiconductor device 100 is mounted, or may be arranged outside the board on which the semiconductor device 100 is mounted.

Since the power supply domain PD2 of FIG. 16 does not have the switch transistor SWT, the buffer BUF22 is used to control the circuit of the power supply domain PD2 or the circuit of the power supply domain PD3. The layout and cross-sectional structure of the AOB of the buffers BUF21, BUF22, BUF23 and the like are identical or similar to the layout and cross-sectional structure of the AOB of the first through fourth embodiments.

As described above, the fifth embodiment can also obtain effects similar to those of the first through fourth embodiments.

Although the present invention has been described above based on the respective embodiments, the present invention is not limited to the requirements illustrated in the above embodiments. These points can be changed within a range not departing from the gist of the present invention, and can be appropriately determined according to the application form.

What is claimed is:

1. A semiconductor device, comprising:
a substrate;
a first power supply line supplied with a first potential, a second power supply line supplied with a second potential, and a third power supply line supplied with a third potential, the first power supply line, the second power supply line, and the third power supply line being formed below the upper surface of the substrate;
a first transistor formed above the substrate and arranged at a position overlapping the first power supply line in a plan view;
a second transistor formed above the substrate; and
a first via formed in the substrate and connected to a source of the first transistor and the first power supply line.

2. The semiconductor device according to claim 1, further comprising:
a second via formed in the substrate and connected to the second power supply line;
a semiconductor layer formed on the substrate and arranged at a position overlapping the second power supply line in a plan view; and
a wiring formed on the substrate and electrically connected to the semiconductor layer and a source of the second transistor.

3. The semiconductor device according to claim 2, further comprising:
a plurality of first circuits each having the first transistor and the second transistor, wherein
the wiring is electrically connected to the source of the second transistor of each of the plurality of first circuits.

4. The semiconductor device according to claim 1, further comprising:
a power supply domain in which the first power supply line, the second power supply line, and the third power supply line are connected to each other, and in which the first potential is constantly supplied to the first power supply line, the second potential is constantly supplied to the second power supply line, and a supply of the third potential to the third power supply line is switched on or off; and
an inverter having the first transistor and the second transistor both of which are arranged in the power supply domain and operating in response to the first potential and the second potential.

5. The semiconductor device according to claim 4, further comprising:
a second via formed in the substrate and connected to the second power supply line and a source of the second transistor arranged at a position overlapping the second power supply line in a plan view, wherein
the first power supply line, the second power supply line, and the third power supply line each extend in a first direction in a plan view,
the first power supply line extending in the first direction is interrupted at a plurality of locations partway along the first power supply line,
the second power supply line is arranged in a region where the first power supply line is interrupted, and
the first transistor and the second transistor are arranged side by side in the first direction in a plan view.

6. The semiconductor device according to claim 4, further comprising:
a second via formed in the substrate and connected to the second power supply line and the source of the second transistor arranged at a position overlapping the second power supply line in a plan view, wherein
the first power supply line, the second power supply line, and the third power supply line each extend in a first direction in a plan view, and
the first transistor and the second transistor are arranged side by side in a second direction different from the first direction in a plan view.

7. The semiconductor device according to claim 6, wherein
the third power supply line extending in the first direction is interrupted at a plurality of locations partway along the third power supply line, wherein
the second power supply line is arranged in a region where the third power supply line is interrupted.

8. The semiconductor device according to claim 1, further comprising:
a first well tap arranged on the substrate and at a position overlapping the first power supply line in a plan view, connected to a third via formed in the substrate, and supplying the first potential to a well of the first transistor; and
a second well tap arranged on the substrate and at a position overlapping the second power supply line in a plan view, connected to a fourth via formed in the substrate, and supplying the second potential to a well of the second transistor.

9. The semiconductor device according to claim 4, further comprising:
a switch transistor connected to the second power supply line and the third power supply line, wherein
an output of the inverter is connected to a gate of the switch transistor.
